(19) United States
(12) Patent Application Publication
(10) Pub. No.: US 2015/0214423 A1
(43) Pub. Date: Jul. 30, 2015

(54) METHOD FOR MANUFACTURING OPTICAL DEVICE AND OPTICAL DEVICE

(71) Applicants: TOKYO ELECTRON LIMITED, Minato-ku (JP); NATIONAL UNIVERSITY CORPORATION NAGOYA UNIVERSITY, Nagoya-shi (JP)

(72) Inventors: Shinya KIKUTA, Tsukuba City (JP); Yoshihiro KATO, Tsukuba City (JP); Koji NEISHI, Tsukuba City (JP); Yoji IIZUKA, Tsukuba City (JP); Hitoshi MIURA, Tsukuba City (JP); Yusaku KASHIWAGI, Tsukuba City (JP); Nobuaki TAKAHASHI, Minato-ku (JP); Hiroshi AMANO, Nagoya-shi (JP); Yoshio HONDA, Nagoya-shi (JP)

(73) Assignees: TOKYO ELECTRON LIMITED, Minato-ku (JP); NATIONAL UNIVERSITY CORPORATION NAGOYA UNIVERSITY, Nagoya-shi (JP)

(21) Appl. No.: 14/481,971

(22) Filed: Sep. 10, 2014

(30) Foreign Application Priority Data
Jan. 29, 2014 (JP) 2014-014187

(51) Int. Cl. H01L 33/00; H01L 33/42; H01L 33/06; H01L 33/24

(52) U.S. Cl. CPC H01L 33/0075; H01L 33/24; H01L 33/42; H01L 33/06

(57) ABSTRACT

A method for manufacturing an optical device includes forming a mask on main surface of a first GaN layer such that the mask has one or more openings in first region on the main surface of the first layer, selectively growing first GaN in the opening such that core including the first GaN is formed on exposed portion of the first layer, forming an active layer on the core such that active region is formed, forming a second GaN layer on the active region, removing a portion of the mask covering second region, forming a first electrode in the second region on the first layer, forming a second electrode covering the second layer and extending onto the mask in third region on the first layer, forming a first pad on the first electrode, and forming a second pad in a pad-forming region of the second electrode in the third region.

### CROSS-REFERENCE TO RELATED APPLICATIONS

The present application is based upon and claims the benefit of priority to Japanese Patent Application No. 2014-014187, filed Jan. 29, 2014, the entire contents of which are incorporated herein by reference.

### BACKGROUND OF THE INVENTION

1. Field of the Invention

The embodiments of the present invention relate to a method for manufacturing an optical device and to the optical device.

2. Description of Background Art

Light-emitting devices have been used as a light source for various purposes, and planar light-emitting devices are generally known. In JP 2013-534050A, a rod-type light-emitting device is described. The entire contents of this publication are incorporated herein by reference.

### SUMMARY OF THE INVENTION

According to one aspect of the present invention, a method for manufacturing an optical device includes forming a mask on a main surface of a first conductive GaN layer such that the mask has one or more opening portions formed in a first region on the main surface of the first conductive GaN layer, selectively growing a first conductive GaN in the opening portion of the mask in the first region such that a core structure including the first conductive GaN is formed on an exposed portion of the first conductive GaN layer, forming an active layer on the core structure such that an active region including the active layer is formed to cover the core structure, forming a second conductive GaN layer on the active region such that the second conductive GaN layer covers the active region including the active layer, removing a portion of the mask covering a second region on the main surface of the first conductive GaN layer, forming a first electrode in the second region on the main surface exposed by the removing of the portion of the mask, forming a second electrode having a pad-forming region such that the second electrode covers the second conductive GaN layer and extends onto the mask in a third region on the main surface of the first conductive GaN layer, forming a first electrode pad on the first electrode, and forming a second electrode pad in the pad-forming region of the second electrode formed in the third region of the main surface of the first conductive GaN layer.

According to another aspect of the present invention, an optical device includes a first conductive GaN layer, a mask covering a main surface of the first conductive GaN layer and having one or more opening portions in a first region and a removed portion in a second region on the main surface of the first conductive GaN layer, a core structure including a first conductive GaN and formed in the opening portion of the mask in the first region such that the core structure is formed on an exposed portion of the first conductive GaN layer, an active layer formed on the core structure such that the active layer forms an active region covering the core structure, a second conductive GaN layer formed on the active region such that the second conductive GaN layer is covering the active region including the active layer, a first electrode formed on the main surface of the first conductive GaN layer such that the first electrode is positioned in the removed portion of the mask in the second region, a second electrode having a pad-forming region and formed such that the second electrode is covering the second conductive GaN layer and extending onto the mask in a third region on the main surface of the first conductive GaN layer, a first electrode pad formed on the first electrode, and a second electrode pad formed in the pad-forming region of the second electrode in the third region on the main surface of the first conductive GaN layer.

### BRIEF DESCRIPTION OF THE DRAWINGS

A more complete appreciation of the invention and many of the attendant advantages thereof will be readily obtained as the same become better understood by reference to the following detailed description when considered in connection with the accompanying drawings, wherein:

FIG. 1 shows a cross-sectional view of an optical device according to an embodiment;

FIG. 2(a)-2(b) show views of a product formed by a step in a method for manufacturing an optical device according to the embodiment;

FIG. 3(a)-3(b) show views of a product formed by a step in the method for manufacturing an optical device according to the embodiment;

FIG. 4(a)-4(c) show views of products formed by steps in the method for manufacturing an optical device according to the embodiment;

FIG. 5(a)-5(b) show views of products formed by steps in the method for manufacturing an optical device according to the embodiment; and

FIG. 6(a)-6(b) show views of products formed by steps in the method for manufacturing an optical device according to the embodiment.

### DETAILED DESCRIPTION OF THE EMBODIMENTS

The embodiments will now be described with reference to the accompanying drawings, wherein like reference numerals designate corresponding or identical elements throughout the various drawings.

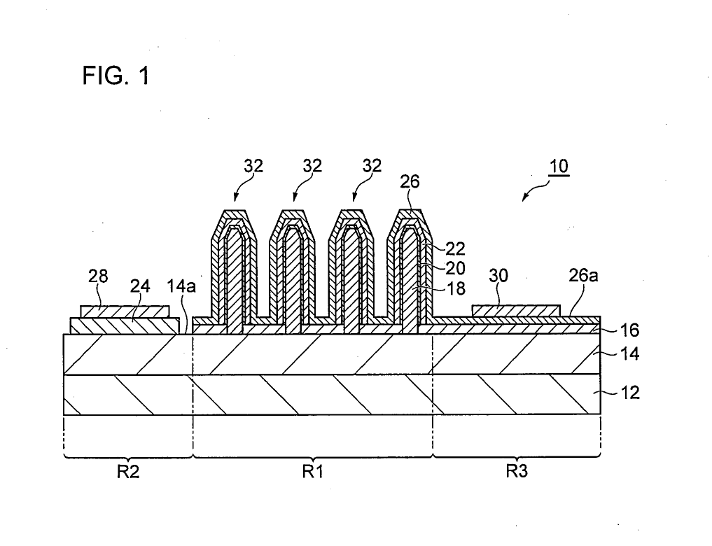

An optical device according to an embodiment is described below. FIG. 1 is a cross-sectional view of an optical device according to the embodiment. Optical device 10 shown in FIG. 1 has substrate 12, first conductive-type GaN layer 14, mask 16, one or more cores 18, active region 20, second conductive-type GaN layer 22, first electrode 24, second electrode 26, first electrode pad 28, and second electrode pad 30.

Substrate 12 may be made of, for example, sapphire, GaN, Si, ZnO, SiC or the like. First conductive-type GaN layer 14 is formed on substrate 12. In the present embodiment, first conductive-type GaN layer 14 is an n-type GaN layer, and may contain impurities such as Si, for example. Here, it is an option to dispose one or more other layers between first conductive-type GaN layer 14 and substrate 12. For example, a buffer layer such as a GaN layer, an AlGaN layer or an AlN layer may be formed on substrate 12. In addition, an undoped GaN layer may further be formed on the buffer layer.

First conductive-type GaN layer 14 has a pair of main surfaces, which are the substrate-12 side main surface and main surface (14a) opposite the substrate-12 side main surface. Main surface (14a) is a substantially flat surface and includes first region (R1), second region (R2) and third region (R3). In the present embodiment, second region (R2) and third region (R3) are positioned diagonally on main surface (14a), while at least partially sandwiching first region (R1). It is an option for third region (R3) to be surrounded by first region (R1), but third region (R3) is set not to overlap first region (R1).

Mask 16 is provided on main surface (14a). Mask 16 is made of SiO₂ or SiN, for example. Mask 16 covers third region (R3). Also, mask 16 covers first region (R1) in such a way that it provides one or more openings. In addition, mask 16 exposes second region (R2).

Core 18 is formed on a portion of first region (R1) exposed by an opening of mask 16. Core 18 is made of first conductive-type GaN, which is selectively grown on the portion of first region (R1) exposed by an opening. Core 18 extends from main surface (14a) in a direction that intersects with main surface (14a). Namely, core 18 extends from a portion of first region (R1) exposed by an opening to protrude beyond mask 16. One example of core 18 is shaped as a rod, and another example of core 18 is shaped as a cone.

On core 18, active region 20 is formed to cover the surface of core 18. Active region 20 is a region that emits light when electric current flows into the region. In the present embodiment, active region 20 may have a multi-quantum-well structure. For example, active region 20 may have a structure formed by alternately laminating one or more active layers made of InGaN, Al(In)GaN or AlGaN and one or more layers made of GaN, Al(In)Gan or AlGaN. More specifically, active region 20 may have any structure among the following various structures: a structure formed by alternately laminating one or more InGaN active layers and one or more layers made of GaN, AlGaN, InGaN or Al(In)GaN; a structure formed by alternately laminating one or more Al(In)GaN active layers and one or more layers made of Al(In)GaN, GaN or AlGaN; a structure formed by alternately laminating one or more AlGaN active layers and one or more AlGaN layers; and the like.

On active region 20, second conductive-type GaN layer 22 is formed to cover active region 20. In the present embodiment, the second conductive type GaN layer is a p-type GaN layer, and may contain impurities such as Mg and Zn, for example. In FIG. 1, second conductive-type GaN layer 22 is formed directly on active region 20; however, a second conductive-type AlGaN electron barrier layer may be disposed between second conductive-type GaN layer 22 and active region 20.

In addition, as shown in FIG. 1, second region (R2) is not covered by mask 16. First electrode 24 is formed on second region (R2). Thus, first electrode 24 is electrically connected to core 18. First electrode 24 may have a multilayer structure formed by laminating, for example, Ti, Al, Ti and Au, in that order.

First electrode pad 28 is formed on first electrode 24. First electrode pad 28 may be formed with, for example, Ti and Au laminated in that order. External wire distribution from optical device 10 is carried out by wire bonding to first electrode 28.

In addition, on second conductive-type GaN layer 22 and on mask 16 formed on third region (R3), second electrode 26 is formed to cover second conductive-type GaN layer 22 and mask 16. In the present embodiment, second electrode 26 is a transparent electrode. Examples of a transparent electrode are those made of ITO, ZnO, TiO₂ or IGZO (InGaZnO₄). Alternatively, second electrode 26 may be a reflecting electrode. Examples of a reflecting electrode are those made of silver or a silver alloy.

Second electrode 26 provides pad-forming region (26a). Pad-forming region (26a) is formed to extend onto third region (R3). In optical device 10, mask 16 is formed on third region (R3) of substantially flat main surface (14a), and mask 16 also provides a substantially flat surface. In addition, pad-forming region (26a) extending onto mask 16 formed on third region (R3) also provides a substantially flat surface. Second electrode pad 30 is formed in pad-forming region (26a). Second electrode 30 is formed with, for example, Ti and Au laminated in that order. Wire bonding to second electrode pad 30 is employed for external wire distribution of optical device 10.

In optical device 10, second electrode pad 30 is formed on pad-forming region (26a), which provides a substantially flat surface. Therefore, contact resistance is low between second electrode pad 30 and second electrode 26. In addition, since adhesiveness is strong between second electrode pad 30 and second electrode 26, peeling of second electrode pad 30 is suppressed when a wire is bonded to second electrode pad 30.

Moreover, second electrode pad 30 is formed not on first region (R1) but on third region (R3), which is different from first region (R1). Namely, second electrode pad 30 is not formed on element section 32 that is structured with core 18, active region 20 and second conductive-type GaN layer 22. In addition, second electrode 26 is a transparent electrode in the present embodiment. Therefore, light is not blocked in the upper portion of element section 32.

In addition, in the present embodiment, second region (R2) and third region (R3) are set on main surface (14a) to be positioned diagonally to each other while at least partially sandwiching first region (R1). Therefore, the difference in electric current supplied to multiple element sections 32 is reduced.

Optical device 10 can be used as a light-emitting device. Optical device 10 is capable of emitting light when electric current is supplied through first electrode pad 28 and second electrode pad 30. In addition, optical device 10 can also be used as a light-receiving device, and is capable of discharging photocurrent based on the light received at element section 32.

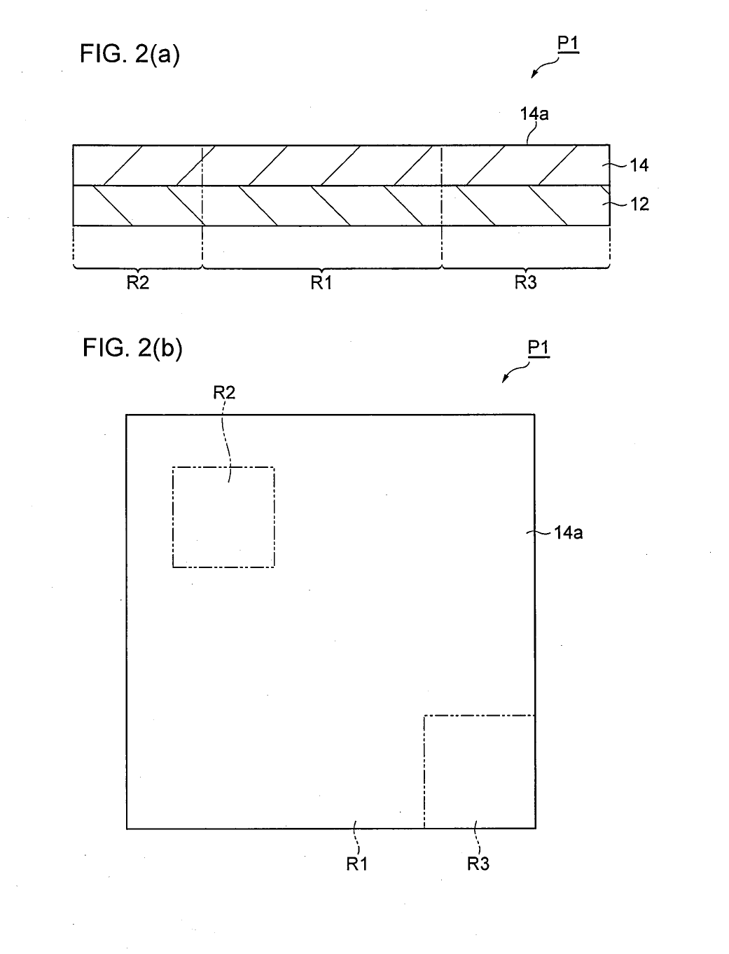

By referring to FIG. 2 through FIG. 6 along with FIG. 1, a method for manufacturing an optical device is described below according to an embodiment of the present invention. FIGS. 2 to 6 are views each showing a product formed by a step in the method for manufacturing an optical device according to the embodiment.

### Formation of First Conductive-Type GaN Layer

FIG. 2 is referred to here. FIG. 2(a) shows a cross-sectional view of product (P1) formed by a step in the present manufacturing method, and FIG. 2(b) shows a plan view seen from above product (P1) formed by a step in the present manufacturing method. In the present manufacturing method, first conductive-type GaN layer 14 is formed on substrate 12 as shown in FIG. 2. First conductive-type GaN layer 14 is formed by using growth process equipment such as MOCVD (Metal Organic Chemical Vapor Deposition) equipment. Accordingly, product (P1) is obtained. Here, prior to forming first conductive-type GaN layer 14, it is an option to form the above-described other layer disposed between first conductive-type GaN layer 14 and substrate 12.

### Formation of Mask

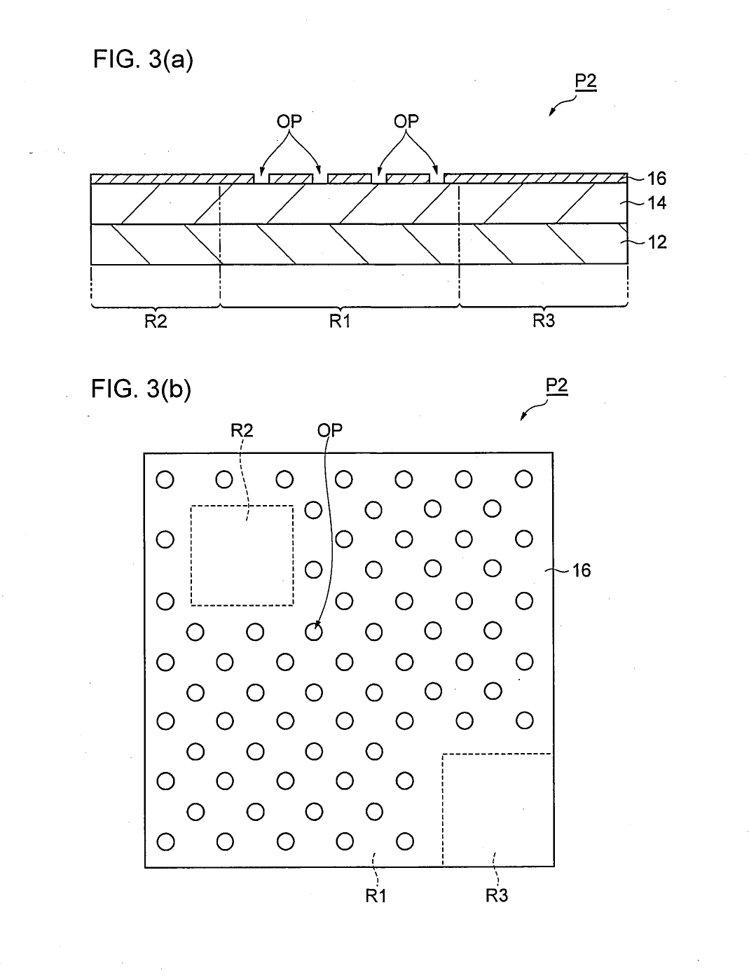

FIG. 3 is referred to here. FIG. 3(a) shows a cross-sectional view of product (P2) formed by a step in the present manufacturing method, and FIG. 3(b) shows a plan view of product (P2), seen from above, formed by a step in the present manufacturing method. As shown in FIG. 3, in the present manufacturing method, mask 16 is formed on first conductive-type GaN layer 14. Mask 16 is formed to cover second region (R2) and third region (R3) at this stage. In addition, mask 16 is also formed on first region (R1) in such a way to provide one or more openings (OP).

More specifically, an insulation layer, which will subsequently become mask 16, is grown on main surface (14a) of first conductive-type GaN layer 14. The insulation layer is made of an SiO₂ layer or SiN layer, for example. Next, the insulation layer is patterned so as to form openings (OP). More specifically, another mask is formed on the insulation layer by a method such as photolithography, nano imprint lithography, electron beam lithography, laser lithography or the like, and then the insulation layer is etched to form mask 16. Accordingly, product (P2) shown in FIG. 3 is obtained. Numerous optical devices 10 are formed on a wafer in the manufacturing process of optical device 10. Thus, openings (OP) are not formed on dicing lines for cutting out individual optical devices 10 from a wafer.

### Formation of Core

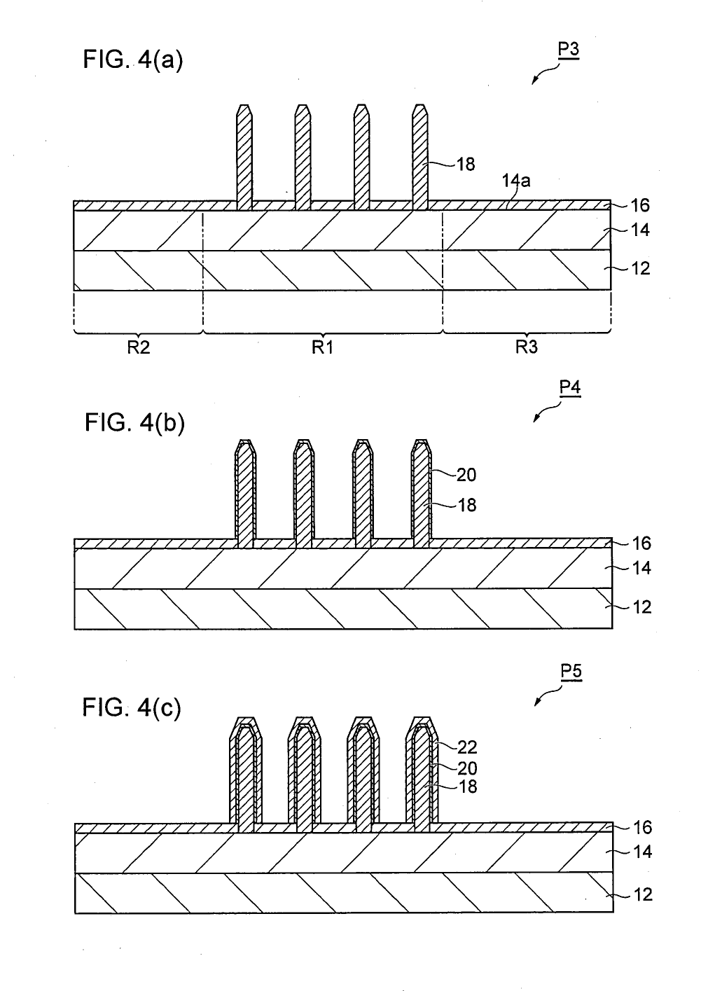

Next, in the present manufacturing method, core 18 is formed as shown in FIG. 4(a). Core 18 is formed on first region (R1) that is exposed from opening (OP). Core 18 is formed by selectively growing first conductive-type GaN on first region (R1) using growth process equipment such as MOCVD equipment. Accordingly, product (P3) shown in FIG. 4(a) is obtained.

### Formation of Active Region

Next, in the present manufacturing method, active region 20 is formed as shown in FIG. 4(b). Active region 20 is formed by selectively growing active region 20 on the surface of core 18. In the present embodiment, active region 20 may be formed using growth process equipment such as MOCVD equipment. As described above, active region 20 may have a multi-quantum-well structure. A multi-quantum-well structure is formed by consecutively growing the aforementioned alternate layers using MOCVD equipment. Accordingly, product (P4) shown in FIG. 4(b) is obtained.

### Formation of Active Region

Next, in the present manufacturing method, second conductive-type GaN layer 22 is formed as shown in FIG. 4(c). Second conductive-type GaN layer 22 is selectively grown on the surface of active region 20. Second conductive-type GaN layer 22 is formed by selectively growing second conductive-type GaN on active region 20 using growth process equipment such as MOCVD equipment. Then, annealing is conducted to activate the impurity (dopant) contained in second conductive-type GaN layer 22. Accordingly, product (P5) shown in FIG. 4(c) is obtained.

### Removal of Mask on Second Region

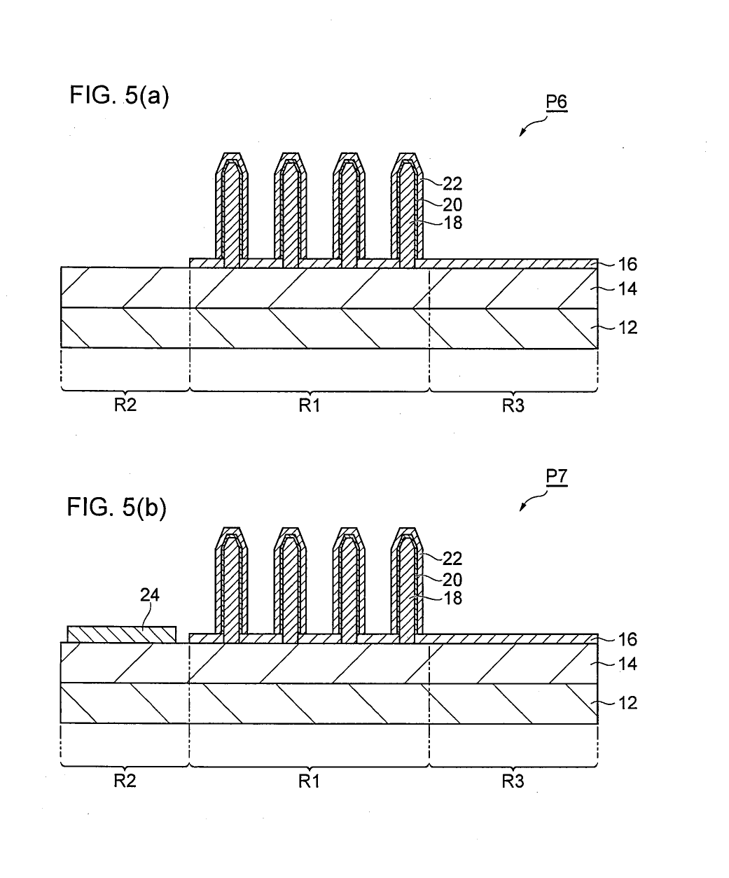

Next, in the present manufacturing method, mask 16 on second region (R2) is removed as shown in FIG. 5(a). By so doing, second region (R2) is exposed. More specifically, a resist mask that exposes mask 16 positioned on second region (R2) is formed by a lithographic process, and mask 16 on second region (R2) is etched so as to expose second region (R2). Accordingly, product (P6) shown in FIG. 5(a) is obtained.

### Formation of First Electrode

Next, in the present manufacturing method, first electrode 24 is formed on second region (R2) as shown in FIG. 5(b). More specifically, a resist mask that exposes second region (R2) is formed, and an electrode material is deposited on second region (R2) by sputtering or by vapor deposition. Then, first electrode 24 is formed by a lift-off process. Accordingly, product (P7) shown in FIG. 5(b) is obtained. Here, it is an option to conduct annealing after the electrode material has been deposited.

### Formation of Second Electrode

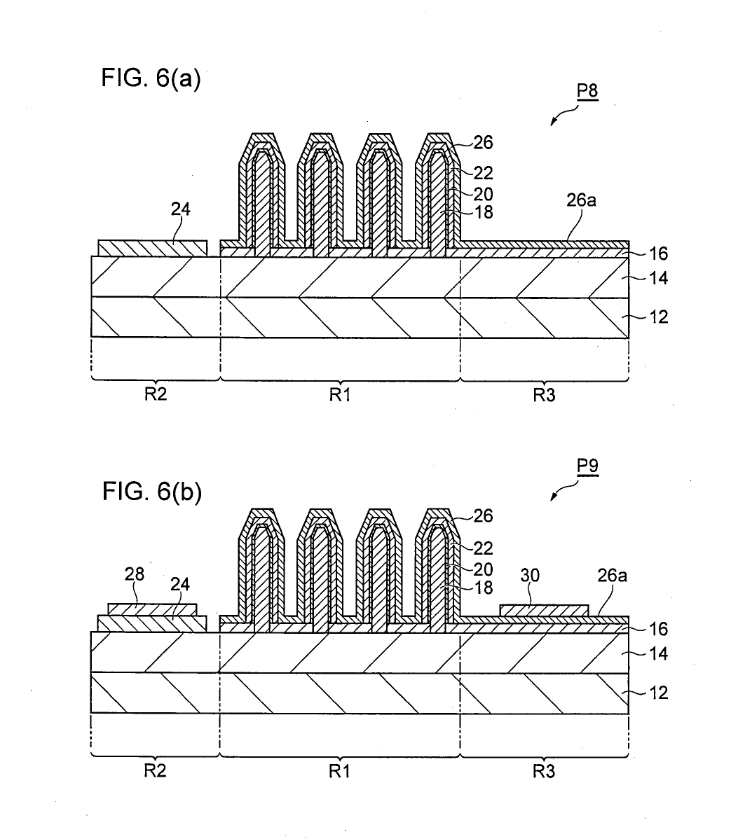

Next, in the present manufacturing method, second electrode 26 is formed on second conductive-type GaN layer 22 and on mask 16 as shown in FIG. 6(a). More specifically, a resist mask that exposes the surface of second conductive-type GaN layer 22 and the surface of mask 16 is formed by lithography, and an electrode material is deposited by sputtering or by vapor deposition on the surface of second conductive-type GaN layer 22 and the surface of mask 16. Then, by conducting a lift-off process, second electrode 26 is formed. Accordingly, product (P8) shown in FIG. 6(a) is obtained. Here, it is an option to conduct annealing after the electrode material has been deposited.

### Formation of First Electrode Pad and Second Electrode Pad

Next, in the present manufacturing method, first electrode pad 28 is formed on first electrode 24 and second electrode pad 30 is formed on pad-forming region (26a) as shown in FIG. 6(b). More specifically, a resist mask that exposes the surface of first electrode 24 and pad-forming region (26a) is formed by lithography, and an electrode material is deposited by sputtering or by vapor deposition on first electrode 24 and on pad-forming region (26a). Then, by conducting a lift-off process, first electrode pad 28 and second electrode pad 30 are formed. Accordingly, product (P9) shown in FIG. 6(b) is obtained. Product (P9) becomes optical device 10 shown in FIG. 1. Therefore, in third region (R3) for forming second electrode pad 30, optical device 10 is structured to have second electrode pad 30, second electrode 26 and mask 16, which are layered on one main surface of first conductive-type GaN layer 14, while no active region 20 is included in third region (R3).

So far, various embodiments of the present invention have been described. However, the present invention is not limited to the embodiments above, and various modifications may be applied. For example, second electrode 26 may be formed as a mesh so as not to be formed on element section 32. Also, the first electrode pad and the second electrode pad were formed at the same time in the above-described manufacturing method, but those electrode pads may be formed in separate steps respectively.

A rod-type light-emitting device is provided with a substrate, multiple cores, an active region, a shell, an n-type electrode, a p-type electrode, a first electrode pad, and a second electrode pad. Multiple cores are formed in a substantially columnar shape, extending in a direction perpendicular to a main surface of the substrate. Multiple cores are formed with an n-type group III-V semiconductor. The active region is the region that emits light when electric current flows, and is formed to cover multiple cores. The shell is a p-type group III-V semiconductor layer, and is formed to cover the active region. The n-type electrode is electrically connected to multiple cores. The first electrode pad is formed on the n-type electrode. In addition, the p-type electrode is formed to cover the multiple rods that are made up of multiple cores, the active region and the shell. The second electrode pad is formed on the p-type electrode, which is formed on at least one of the multiple rods. In a rod-type light-emitting device, wires are bonded to the first electrode pad and the second electrode pad respectively.

In the above-described rod-type light-emitting device, since a second electrode pad is provided on the p-type electrode formed on the upper portion of a rod, contact resistance may increase between the second electrode pad and the p-type electrode. In addition, the second electrode pad may be peeled off from the p-type electrode during wire bonding.

Thus, a method for manufacturing an optical device capable of forming electrode pads that have low contact resistance and are hard to remove as well as an optical device with such properties has been in demand.

A method for manufacturing an optical device according to an embodiment of the present invention includes the following: (a) a step for forming a mask on one main surface of a first conductive-type GaN layer, where the one main surface includes a first region, a second region and a third region, and the mask has one or more opening portions in the first region while covering the second and third regions; (b) in portions of the first region exposed by openings of the mask, a step for selectively growing first conductive-type GaN; (c) a step for forming an active region to cover a core formed by the step for selectively growing first conductive-type GaN; (d) a step for forming a second conductive-type GaN layer to cover the active region; (e) a step for removing the mask on the second region; (f) a step for forming a first electrode on the second region; (g) a step for forming a first electrode pad on the first electrode; (h) a step for forming a second electrode on the second conductive-type GaN layer and on the mask formed on the third region, where the second electrode provides a pad-forming region on the mask positioned on the third region; and (i) a step for forming a second electrode pad on the pad-forming region.

The third region provides a substantially flat surface. The mask formed on the third region also provides a substantially flat surface. Thus, the pad-forming region extending on the mask formed on the third region provides a substantially flat surface as well. In the present manufacturing method, since a second electrode pad is formed on the pad-forming region, contact resistance decreases between the second electrode pad and the second electrode. Also, since the adhesiveness of the second electrode pad to the second electrode is strong, removal of the second electrode pad from the second electrode during wire bonding is suppressed.

The second electrode may be a transparent electrode in an embodiment. In such an embodiment, a second electrode pad is not formed on an element section which is formed with a core, an active region and a second conductive-type GaN layer, and the second electrode is a transparent electrode. Thus, light is not blocked by the second electrode pad in the upper portion of the element section.

In an embodiment, the second and third regions may be positioned diagonally, at least partially sandwiching the first region. According to such an embodiment, the difference in electric current supplied to multiple element sections made up of a core, an active region and a second conductive-type GaN layer is reduced.

In addition, an optical device is provided according to another aspect of the present invention. The optical device is formed with a first conductive-type GaN layer, a mask, a core, a second conductive-type GaN layer, a first electrode, a first electrode pad, a second electrode and a second electrode pad. The first conductive-type GaN layer has one main surface. The one main surface includes a first region, a second region and a third region. The mask provides one or more openings on the first region and covers the third region. The core is formed on the portion of the first region exposed from an opening of the mask by selectively growing first conductive-type GaN. The active region is formed to cover the core. The second conductive-type GaN layer is formed to cover the active region. The first electrode is formed on the second region, and the first electrode pad is formed on the first electrode. The second electrode is formed to extend onto the second conductive-type GaN layer and the mask on the third region. The second electrode provides a pad-forming region on the mask positioned on the third region. The second electrode pad is formed on the pad-forming region.

In an embodiment of the present invention, the second electrode may be a transparent electrode. Also, in an embodiment of the present invention, the second and third regions may be positioned diagonally while at least partially sandwiching the first region.

Using a method for manufacturing an optical device according to an embodiment of the present invention and an optical device according to another embodiment of the present invention, an electrode pad is formed to have low contact resistance and to be hard to peel off.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing an optical device, comprising:
forming a mask on a main surface of a first conductive GaN layer such that the mask has at least one opening portion formed in a first region on the main surface of the first conductive GaN layer;
selectively growing a first conductive GaN in the opening portion of the mask in the first region such that a core structure comprising the first conductive GaN is formed on an exposed portion of the first conductive GaN layer;
forming an active layer on the core structure such that an active region comprising the active layer is formed to cover the core structure;
forming a second conductive GaN layer on the active region such that the second conductive GaN layer covers the active region comprising the active layer;
removing a portion of the mask covering a second region on the main surface of the first conductive GaN layer;
forming a first electrode in the second region on the main surface exposed by the removing of the portion of the mask;
forming a second electrode having a pad-forming region such that the second electrode covers the second conductive GaN layer and extends onto the mask in a third region on the main surface of the first conductive GaN layer;
forming a first electrode pad on the first electrode; and
forming a second electrode pad in the pad-forming region of the second electrode formed in the third region of the main surface of the first conductive GaN layer.

2. A method for manufacturing an optical device according to claim 1, wherein the opening portion of the mask is formed in the mask in a plurality, and the first conductive GaN is selectively grown on a plurality of exposed portions exposed by the plurality of opening portions of the mask in the first region such that a plurality of core structures comprising the first conductive GaN is formed on the exposed portions of the first conductive GaN layer.

3. A method for manufacturing an optical device according to claim 1, wherein the second electrode is a transparent electrode.

4. A method for manufacturing an optical device according to claim 2, wherein the second electrode is a transparent electrode.

5. A method for manufacturing an optical device according to claim 1, wherein the second region and the third region are diagonally positioned with respect to each other such that at least portion of the first region is interposed between the second region and the third region.

6. A method for manufacturing an optical device according to claim 2, wherein the second region and the third region are diagonally positioned with respect to each other such that at least portion of the first region is interposed between the second region and the third region.

7. A method for manufacturing an optical device according to claim 3, wherein the second region and the third region are diagonally positioned with respect to each other such that at least portion of the first region is interposed between the second region and the third region.

8. A method for manufacturing an optical device according to claim 4, wherein the second region and the third region are diagonally positioned with respect to each other such that at least portion of the first region is interposed between the second region and the third region.

9. A method for manufacturing an optical device according to claim 1, wherein the forming of the active layer comprises forming the active layer having a laminated structure comprising a plurality of active layers.

10. A method for manufacturing an optical device according to claim 1, wherein the forming of the active layer comprises forming the active layer having a multi-quantum-well structure on the core structure.

11. An optical device, comprising:
a first conductive GaN layer;
a mask covering a main surface of the first conductive GaN layer and having at least one opening portion in a first region and a removed portion in a second region on the main surface of the first conductive GaN layer;
a core structure comprising a first conductive GaN and formed in the opening portion of the mask in the first region such that the core structure is formed on an exposed portion of the first conductive GaN layer;
an active layer formed on the core structure such that the active layer forms an active region covering the core structure;
a second conductive GaN layer formed on the active region such that the second conductive GaN layer is covering the active region comprising the active layer;
a first electrode formed on the main surface of the first conductive GaN layer such that the first electrode is positioned in the removed portion of the mask in the second region;
a second electrode having a pad-forming region and formed such that the second electrode is covering the second conductive GaN layer and extending onto the mask in a third region on the main surface of the first conductive GaN layer;
a first electrode pad formed on the first electrode; and
a second electrode pad formed in the pad-forming region of the second electrode in the third region on the main surface of the first conductive GaN layer.

12. An optical device according to claim 11, wherein the opening portion of the mask is formed in the mask in a plurality, and the core structure is formed in a plurality in a plurality of opening portions of the mask, respectively.

13. An optical device according to claim 11, wherein the second electrode is a transparent electrode.

14. An optical device according to claim 12, wherein the second electrode is a transparent electrode.

15. An optical device according to claim 11, wherein the second region and the third region are diagonally positioned with respect to each other such that at least portion of the first region is interposed between the second region and the third region.

16. An optical device according to claim 12, wherein the second region and the third region are diagonally positioned with respect to each other such that at least portion of the first region is interposed between the second region and the third region.

17. An optical device according to claim 13, wherein the second region and the third region are diagonally positioned with respect to each other such that at least portion of the first region is interposed between the second region and the third region.

18. An optical device according to claim 14, wherein the second region and the third region are diagonally positioned with respect to each other such that at least portion of the first region is interposed between the second region and the third region.

19. An optical device according to claim 11, wherein the active layer has a laminated layer structure comprising a plurality of active layers.

20. An optical device according to claim 11, wherein the active layer has a multi-quantum well structure.
